(19) United States
(12) Patent Application Publication
(10) Pub. No.: US 2018/0366316 A1
(43) Pub. Date: Dec. 20, 2018

(54) METHOD FOR CLEANING SEMICONDUCTOR DEVICE

(71) Applicant: United Microelectronics Corp., Hsinchu (TW)

(72) Inventors: Chun-Jung Wang, Taichung City (TW); Chia-Ming Lee, Tainan City (TW); Tsung-Hsun Tsai, Chiayi County (TW); Kuo-Wei Chih, Tainan City (TW); Chia-Yen Hsu, Kaohsiung City (TW)

(73) Assignee: United Microelectronics Corp., Hsinchu (TW)

(21) Appl. No.: 15/623,186

(22) Filed: Jun. 14, 2017

(51) Int. Cl. H01L 21/02; B08B 3/08; B08B 3/10

(52) U.S. Cl. CPC H01L 21/02057; B08B 3/10; B08B 3/08

(57) ABSTRACT

A method is provided for cleaning a semiconductor structure. The method includes performing a rinse process of CO₂ with water (CO2W) process over the semiconductor structure; and performing a standard clean (SC) process over the semiconductor structure with an overlapping period with the step of performing the rinse process of CO2W.

### BACKGROUND

### 1. Field of the Invention

The present invention generally relates to semiconductor fabrication, and particularly to a method for cleaning a semiconductor device.

### 2. Description of Related Art

As usually known, the integrated circuit device is fabricated by semiconductor fabrication technology. In fabrication, a large number of semiconductor devices are formed on a wafer before cutting into dies. Various fabrication processes are performed to form the semiconductor structure as designed. Various chemical materials respectively are involved in the fabrication processes, such as etching process. A cleaning procedure is usually needed to remove the chemical residuals, which may be from the cleaning solution or the materials on the wafer to be cleaned. However, the cleaning procedure uses chemical agent, which may include water and/or acid, to clean dielectric, resulting in chemical residuals in the cleaning solution.

However, even if the cleaning procedure is performed, there is little amount of cleaning residuals may still remain at the edge of the wafer due to the semiconductor structure with uneven surface. After drying, the cleaning residuals would remain on the wafer as called the water mark. If the water mark is serious, the performance of the semiconductor device would degrade, resulting in poor performance.

How to reduce the water mark, or the cleaning residuals, is still an issue tp be concerned in semiconductor fabrication.

### SUMMARY OF THE INVENTION

The invention provides a method for cleaning the semiconductor device, in which the water mark can be effectively removed, so to improve the cleaning quality.

In an embodiment, the invention provides a method for cleaning a semiconductor structure. The method comprises performing a rinse process of CO₂ with water (CO2W) process over the semiconductor structure; and performing a standard clean (SC) process over the semiconductor structure with an overlapping period with the step of performing the rinse process of CO2W.

In an embodiment, as to the method, the SC process comprises a standard clean 1 (SC1) process or a standard clean 2 (SC2) process.

In an embodiment, as to the method, the semiconductor structure comprises a wafer or a wafer with a structure already formed on the wafer.

In an embodiment, as to the method, the semiconductor structure comprises a structure with a trench or a structure with a significant large aspect ratio.

In an embodiment, as to the method, the overlapping period is in a range of 0.5 s-2 s.

In an embodiment, as to the method, the overlapping period is 1 s.

In an embodiment, as to the method, the method further comprises a diluted hydrofluoric (DHF) process before performing the rinse process of CO2W.

In an embodiment, as to the method, during the rinse process of CO2W, a recipe of the SC process has been applied to the semiconductor structure by the overlapping period.

In an embodiment, as to the method, during the rinse process of CO2W, the substrate is in a rotating state.

In an embodiment, as to the method, the semiconductor structure has a hydrophobic surface under cleaning.

In an embodiment, the invention provides a method for processing a semiconductor device, comprising forming a semiconductor structure over a substrate. Performing a cleaning process of diluted hydrofluoric (DHF) acid over the semiconductor structure. Further, a rinse process of CO₂ with water (CO2W) is performed over the semiconductor structure after the cleaning process of DHF acid. A standard clean (SC) process is performed over the semiconductor structure with an overlapping period with the step of performing the rinse process of CO2W.

In an embodiment, as to the method, the SC process comprises a standard clean 1 (SC1) process or a standard clean 2 (SC2) process.

In an embodiment, as to the method, the semiconductor structure comprises a wafer or a wafer with a structure already formed on the wafer.

In an embodiment, as to the method, the semiconductor structure comprises a structure with a trench or a structure with a significant large aspect ratio.

In an embodiment, as to the method, the overlapping period is in a range of 0.5 s-2 s.

In an embodiment, as to the method, the overlapping period is 1 s.

In an embodiment, as to the method, the method further comprises a drying process after the SC1 process.

In an embodiment, as to the method, during the rinse process of CO2W, a recipe of the SC process has been applied to the semiconductor structure by the overlapping period.

In an embodiment, as to the method, during the rinse process of CO2W, the substrate is in a rotating state.

In an embodiment, as to the method, the semiconductor structure has a hydrophobic surface under cleaning.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a drawing, schematically illustrating a mechanism causing water mark occurring on a wafer, according to an embodiment of the invention.

FIG. 2 is a drawing, schematically illustrating the water mark of cleaning residuals occurring on the wafer, according to an embodiment of the invention.

FIG. 3 is a drawing, schematically illustrating a usual cleaning procedure over a wafer, as looked into, according to an embodiment of the invention.

FIG. 4 is a drawing, schematically illustrating a cleaning procedure over a wafer, according to an embodiment of the invention.

FIG. 5 is a drawing, schematically illustrating a cleaning procedure over a wafer, according to an embodiment of the invention.

FIG. 6 is a drawing, schematically illustrating a wafer state after cleaning procedure, according to an embodiment of the invention.

### DESCRIPTION OF THE EMBODIMENTS

The invention is directed to a technology for cleaning semiconductor device formed over a wafer. The invention proposes a cleaning procedure, so that the water mark as the cleaning residuals can be effectively reduced, so to improve the cleaning quality.

The invention has looked into the cleaning procedure to find the mechanism in causing the water mark. Then invention has also proposes the solution to reduce the water mark. Several embodiments are provided for describing the invention but not for limiting the invention.

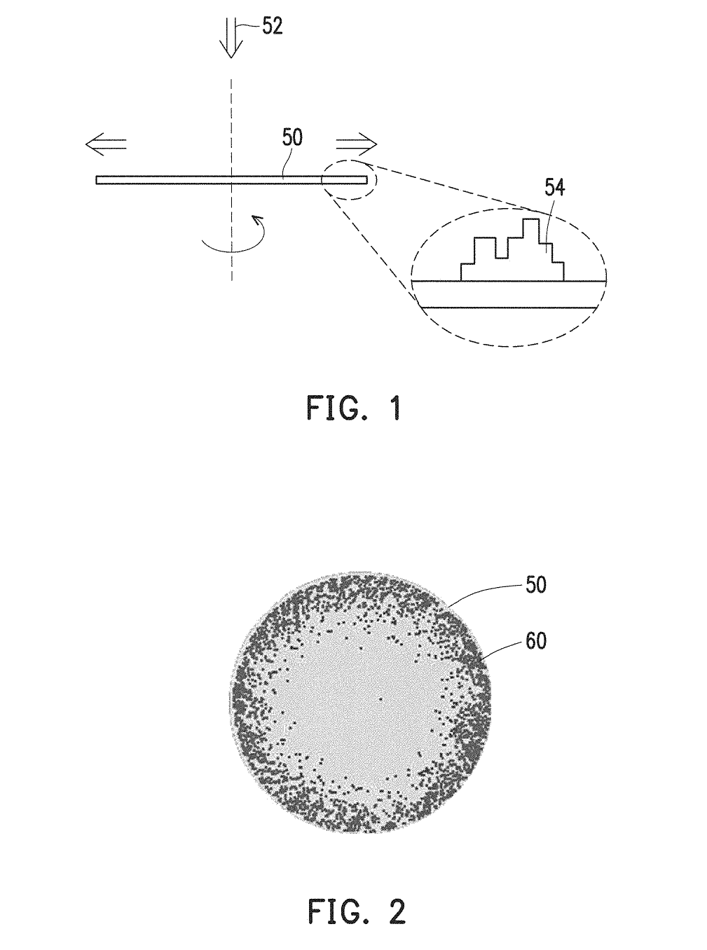

FIG. 1 is a drawing, schematically illustrating a mechanism causing water mark occurring on a wafer, according to an embodiment of the invention. Referring to FIG. 1, a large number of semiconductor devices 54 with the structure are formed over the wafer 50. The structure of the semiconductor devices 54 usually include the trenches and the protruding part with large aspect ratio. During the cleaning procedure 52 over the semiconductor devices 54, the cleaning solution, such as water with cleaning chemical agents, are dispensed onto the wafer 50. The wafer 50 is rotated to release the cleaning solution.

The cleaning solution usually includes some chemical materials, such as acid or dielectric residuals. Most of the cleaning solution are driven away from the wafer due to the rotation of the wafer 50. However, the structure of the semiconductor 54 is not a smooth surface, so some cleaning solution may still remain at the edge of the wafer 50. After the cleaning solution is dried, the chemical residuals in the cleaning solution leaves on the semiconductor device 54 over the wafer 50, resulting in water mark.

FIG. 2 is a drawing, schematically illustrating the water mark of cleaning residuals occurring on the wafer, according to an embodiment of the invention. Referring to FIG. 2, the water mark 60 have been observed after the usual cleaning procedure. The water mark 60 remains on the semiconductor devices 54 on the wafer and affects the quality of the semiconductor devices 54. Thereby, the water mark would cause the poor performance or even a failure of the semiconductor device as fabricated at the end. Generally, the water mark is easily appearing at trench structure or high aspect ratio structure in an example.

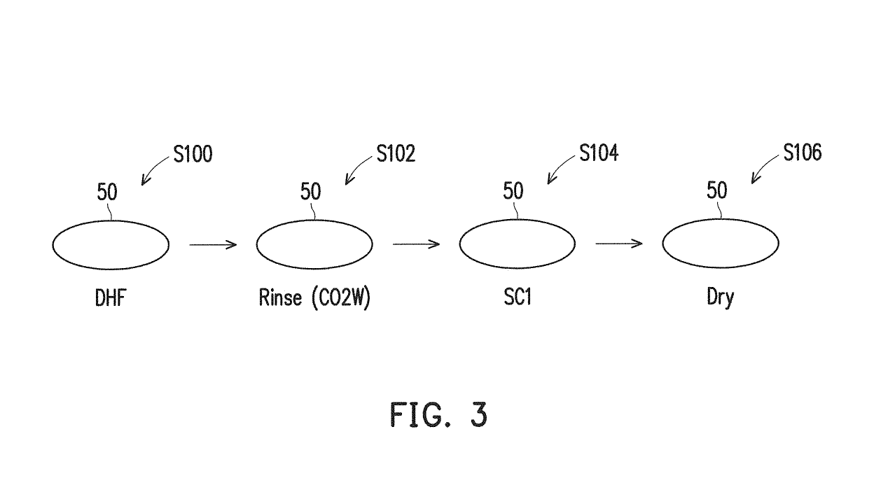

The water mark 60 has been observed in the usual cleaning procedure. FIG. 3 is a drawing, schematically illustrating a usual cleaning procedure over a wafer, as looked into, according to an embodiment of the invention.

Referring to FIG. 3, the cleaning procedure in step S100 perform a diluted hydrofluoric (DHF) process, in which the DHF acid is applied over the wafer 50 to remove the residuals after fabrication process, such as etching process, but not limited to. In step S102, the rinse process using a cleaning agent of CO₂ with water (CO2W) is performed. In step S104, a cleaning process using recipe of stander clean 1 (SC1) is performed again on the wafer 50. One of recipes of SC1 in an example includes 5 parts of deionized water, 1 part of aqueous NH₄OH (ammonium hydroxide, 29% by weight of NH₃) and one part of aqueous H₂O₂ (hydrogen peroxide, 30%). After then, in step S106, the wafer 50 is performed by drying process, in which another rinse process may also applied before drying if it is intended.

After looking into the cleaning procedure with the observation of the water mark leaving on the wafer in various samples, the invention has identified the factor, which may cause the water mark. The water mark may more seriously occur due to the residuals between the rinse process in step S102 and the SC1 process in step S104.

After investigating the issue in detail, the cleaning procedure may be modified by over lapping the rinse process in step S102 and the SC1 process in step S104 by a certain period, such as 1 second or even in range of 0.5 s to 2 s.

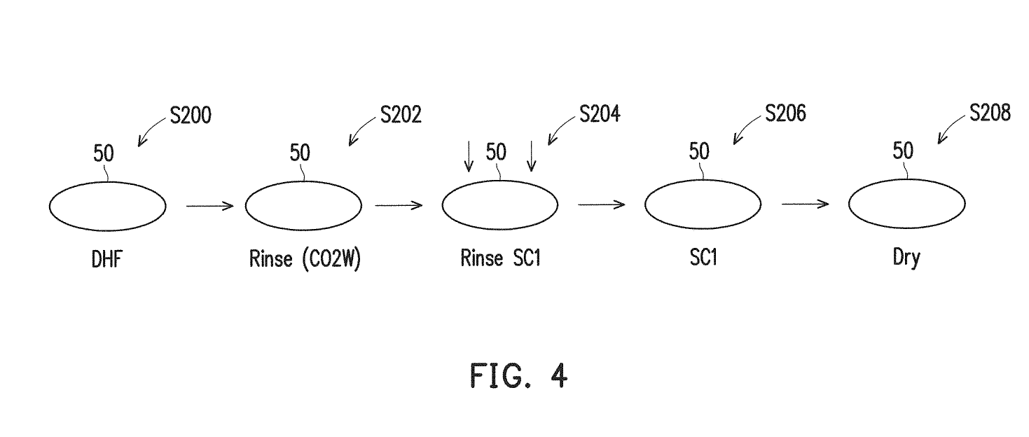

FIG. 4 is a drawing, schematically illustrating a cleaning procedure over a wafer, according to an embodiment of the invention. Referring to FIG. 4, in step S200, a diluted hydrofluoric (DHF) process is performed by applying the DHF acid over the wafer 50. In step S200, the rinse process with CO2W as the cleaning solution is performed over the wafer 50.

In step S204, the invention starts the SC1 process together with the rinse process of CO2W in step S202 by a time period by 1 second or even in range of 0.5 s to 2 s. In other words, the SC1 process starts before the rinse process of CO2W in step S202 has finished. The rinse process of CO2W in step S204 is the end part of the rinse process of CO2W in step S202.

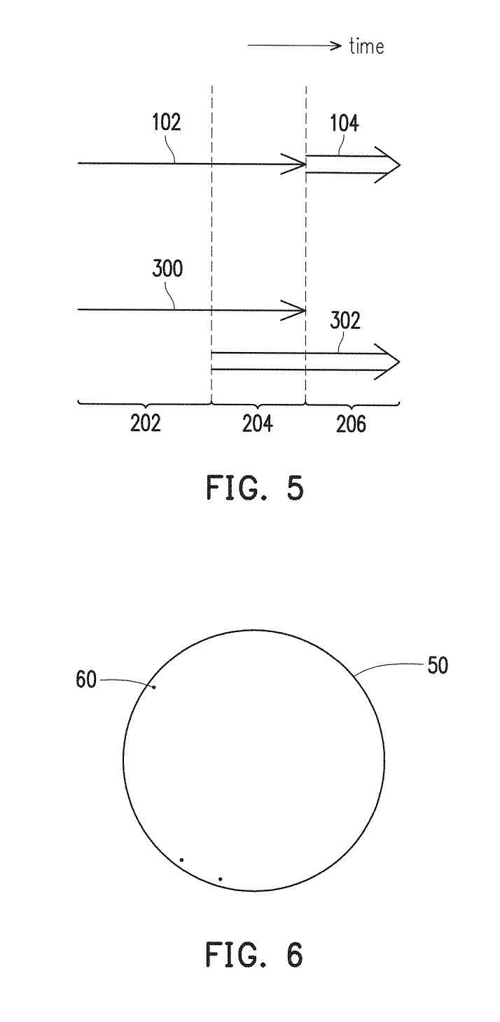

FIG. 5 is a drawing, schematically illustrating a cleaning procedure over a wafer, according to an embodiment of the invention. To further understand the operation mechanism, FIG. 5 is referred. The cleaning procedure in FIG. 3 is shown at to upper flow and the cleaning procedure in FIG. 4 is shown at the lower flow. In the upper flow with respect to FIG. 3, the rinse process 102 of CO2W in step S102 is performed. And the SC1 process 104 is performed after the rinse process 102.

In lower flow corresponding to FIG. 4, the stage 202 involves the rinse process 300 as usual. However, in stage 204 corresponding to step S204, the SC1 process 302 starts with the overlapping range. And then, the rinse process 300 stops at the stage 206. In other words, the invention proposes that performing a standard clean (SC) process over the semiconductor structure with an overlapping period with the step of performing the rinse process of CO2W. The SC process can be the SC1 process or the SC2 process in different recipe as usually known in the cleaning procedure.

After the step S206 with completion of the SC1 process, the wafer 50 can be dried in step S208. An additional rinse process in an example may be applied again before drying the wafer 50. However, this is not the limitation. Also, the wafer 50 may be rotated with proper rotation speed, so to effectively remove the cleaning solution. However, the rotation of the wafer is also not the limitation. The wafer 50 can has no rotation in an example.

FIG. 6 is a drawing, schematically illustrating a wafer state after cleaning procedure, according to an embodiment of the invention. Referring to FIG. 6, after the cleaning procedure based on the flow in FG. 4 or FIG. 5, the water mark 60 can be effectively reduced as have been observed in practical samples.

The invention proposes a new cleaning process to improve the wafer mark by overlapping the rinse process of CO2W after the DHF with the SC1 process by a short period, such as 1 second or 0.5 s-2 s. In other words, the recipes of CO2W and SC1 are mixed during this short period. In this situation, a hydrophobic surface can be created under cleaning process, the chemical residuals can be effectively rinsed away from the semiconductor device.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for cleaning a semiconductor structure, comprising:
performing a rinse process of CO₂ with water (CO2W) over the semiconductor structure; and
performing a standard clean (SC) process over the semiconductor structure with an overlapping period with the step of performing the rinse process of CO₂ with water.

2. The method of claim 1, wherein the SC process comprises a standard clean 1 process or a standard clean 2 process.

3. The method of claim 1, wherein the semiconductor structure comprises a wafer or a wafer with a structure already formed on the wafer.

4. The method of claim 1, wherein the semiconductor structure comprises a structure with a trench or a structure with a significant large aspect ratio.

5. The method of claim 1, wherein the overlapping period is in a range of 0.5 s-2 s (204).

6. The method of claim 1, wherein the overlapping period is 1 s.

7. The method of claim 1, further comprising a diluted hydrofluoric (DHF) process before performing the rinse process of CO2W.

8. The method of claim 1, wherein during the rinse process of CO2W, a recipe of the SC process has been applied to the semiconductor structure by the overlapping period.

9. The method of claim 1, wherein during the rinse process of CO2W, the substrate is in a rotating state.

10. The method of claim 1, wherein the semiconductor structure has a hydrophobic surface under cleaning.

11. A method for processing a semiconductor device, comprising:
forming a semiconductor structure over a substrate;
performing a cleaning process of diluted hydrofluoric (DHF) acid over the semiconductor structure;
performing a rinse process of CO₂ with water (CO2W) over the semiconductor structure after the cleaning process of DHF acid; and
performing a standard clean (SC) process over the semiconductor structure with an overlapping period with the step of performing the rinse process of CO2W.

12. The method of claim 11, wherein the SC process comprises a standard clean 1 process or a standard clean 2 process.

13. The method of claim 11, wherein the semiconductor structure comprises a wafer or a wafer with a structure already formed on the wafer.

14. The method of claim 11, wherein the semiconductor structure comprises a structure with a trench or a structure with a significant large aspect ratio.

15. The method of claim 11, wherein the overlapping period is in a range of 0.5 s-2 s.

16. The method of claim 11, wherein the overlapping period is 1 s.

17. The method of claim 11, further comprising a drying process after the SC1 process.

18. The method of claim 11, wherein during the rinse process of CO2W, a recipe of the SC process has been applied to the semiconductor structure by the overlapping period.

19. The method of claim 11, wherein during the rinse process of CO2W, the substrate is in a rotating state.

20. The method of claim 11, wherein the semiconductor structure has a hydrophobic surface under cleaning.
